(19) United States
(12) Patent Application Publication
(10) Pub. No.: US 2025/0147095 A1
(43) Pub. Date: May 8, 2025

(54) POWER DEVICE CHARACTERIZATION ON THE WAFER USING AUTOMATED PARAMETRIC SYSTEM

(71) Applicant: Keithley Instruments, LLC, Solon, OH (US)

(72) Inventors: Alexander N. Pronin, Twinsburg, OH (US); Jin Kwang Yu, Hudson, OH (US)

(73) Assignee: Keithley Instruments, LLC, Solon, OH (US)

(21) Appl. No.: 19/012,294

(22) Filed: Jan. 7, 2025

Related U.S. Application Data
(63) Continuation-in-part of application No. 18/626,190, filed on Apr. 3, 2024.
Application No. 18/626,190 is a continuation-in-part of application No. 17/688,733, filed on Mar. 7, 2022.
(60) Provisional application No. 63/620,366, filed on Jan. 12, 2024.
(60) Provisional application No. 63/458,075, filed on Apr. 7, 2023.
(60) Provisional application No. 63/464,143, filed on May 4, 2023.
(60) Provisional application No. 63/523,836, filed on Jun. 28, 2023.
(60) Provisional application No. 63/161,382, filed on Mar. 15, 2021.
(60) Provisional application No. 63/260,513, filed on Aug. 23, 2021.

(51) Int. Cl. G01R 31/26; G01R 31/14

(52) U.S. Cl. CPC G01R 31/2639; G01R 31/14

(57) ABSTRACT

In some examples, the system may include a parametric system matrix coupled one or more test and measurement instruments. Also, the system may include an adapter circuit coupled to the parametric system matrix, the adapter circuit having a voltage clamping circuit coupled to the parametric system matrix. Furthermore, the system may include a probe circuit coupled to the adapter circuit and to the power device, where the power device is disposed on a wafer.

### CROSS-REFERENCE TO RELATED APPLICATIONS

This application is a continuation-in-part application of U.S. Nonprovisional application Ser. No. 18/626,190, titled “UNIFIED MEASUREMENT SYSTEM FOR STATIC AND DYNAMIC CHARACTERIZATION OF A DEVICE UNDER TEST,” filed on Apr. 3, 2024, which, in turn, claims the benefit of U.S. Provisional Patent Application No. 63/458,075, titled “IMPEDANCE MEASUREMENT OF A DEVICE UNDER TEST ON A COMBINED STATIC AND DYNAMIC CHARACTERIZATION PLATFORM,” filed Apr. 7, 2023, the benefit of U.S. Provisional Patent Application No. 63/464,143, titled “BODY DIODE CHARACTERIZATION ON A UNIFIED MEASUREMENT SYSTEM FOR STATIC AND DYNAMIC CHARACTERIZATION OF A DEVICE UNDER TEST,” filed May 4, 2023, and the benefit of U.S. Provisional Patent Application No. 63/523,836, titled “GATE CHARGE CHARACTERIZATION OF A DEVICE UNDER TEST ON A UNIFIED STATIC AND DYNAMIC TEST PLATFORM,” filed Jun. 28, 2023, and is a continuation-in-part application of U.S. Nonprovisional application Ser. No. 17/688,733, titled “UNIFIED MEASUREMENT SYSTEM FOR STATIC AND DYNAMIC CHARACTERIZATION OF A DEVICE UNDER TEST,” filed on Mar. 7, 2022, which, in turn, claims the benefit of U.S. Provisional Patent Application No. 63/161,382, titled “UNIFIED MEASUREMENT SYSTEM FOR STATIC AND DYNAMIC CHARACTERIZATION OF A DEVICE UNDER TEST,” filed Mar. 15, 2021, and the benefit of U.S. Provisional Patent Application No. 63/260,513, titled “HIGH POWER STATIC AND DYNAMIC DUT CHARACTERIZATION,” filed Aug. 23, 2021. This application also claims benefit of U.S. Provisional Application No. 63/620,350, titled “SEARCH FUNCTION WITH DEVICE MODELING,” filed on Jan. 12, 2024. The disclosures of each of these applications are incorporated herein by reference in their entirety.

### TECHNICAL FIELD

This disclosure relates to test and measurement systems, more particularly to systems and methods for performing static and dynamic characterization of devices.

### BACKGROUND

Characterization of a device under test (DUT), for example semiconductor devices such as a silicon-carbide (SiC) metal-oxide-semiconductor field-effect transistor (MOSFET), may generally include both static characterization, such as current/voltage (I/V) curves, and dynamic characterization, such as switching parameters. Conventional static characterization involves use of a dedicated static measurement platform. Additionally, conventional dynamic characterization of a DUT involves a different measurement platform, in some cases a dedicated custom dynamic platform.

Numerous products currently exist in the market for characterizing power devices and power modules, encompassing tests like dynamic assessments (e.g., Double Pulse Test, Dynamic R_{DS}_{ₒₙ}, leakage, breakdown). Typically, these evaluations are performed on packaged parts or modules. Dynamic tests usually involve combining a scope with a capacitor bank, facilitating high voltage and high current testing.

Challenges arise in combining power measurements (e.g., dynamic RDSon, double pulse test) with parametric testing in an automated manner on wafers. Presently, no commercially available solution exists that can carry out production-level characterization of power devices on wafers, incorporate parametric-sensitive measurements, and meet the speed requisites of production processes.

Embodiments of the disclosed apparatus and methods address shortcomings in the prior art.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 shows an example of a conventional dedicated static characterization measurement platform.

FIG. 2 shows an example of a conventional dedicated dynamic characterization measurement platform.

FIG. 3 shows an embodiment of a test and measurement system, according to embodiments of the disclosure.

FIG. 4 shows an embodiment of a characterization circuit for characterizing parameters of one or more DUTs in conjunction with the test and measurement system of FIG. 3, according to embodiments of the disclosure.

FIG. 5 shows an embodiment of a characterization circuit including a selection switch for independently characterizing parameters of two DUTs in conjunction with the test and measurement system of FIG. 3, according to embodiments of the disclosure.

FIG. 6 is a schematic diagram of an example characterization circuit for static and dynamic characterization of one or more DUTs in conjunction with the test and measurement system of FIG. 3, according to embodiments of the disclosure.

FIG. 7 is a schematic of a solid-state bias tee that may be utilized in the characterization circuits of FIGS. 6, 8 and 9, according to embodiments of the disclosure.

FIG. 8 is a schematic diagram of another example characterization circuit for static and dynamic characterization of one or more DUTs in conjunction with the test and measurement system of FIG. 3, according to embodiments of the disclosure.

FIG. 9 is a schematic diagram of an example characterization circuit for gate charge characterization and body diode characterization of one or more DUTs in conjunction with the test and measurement system of FIG. 3, according to embodiments of the disclosure.

FIG. 10 shows an example of a characterization measurement platform coupled to a wafer for testing, according to some examples.

FIG. 11 shows an embodiment of a test and measurement system, according to embodiments of the disclosure.

FIG. 12 is a flowchart of testing a power device on a wafer using the test and measurement system of FIG. 11, according to some examples.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the description or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

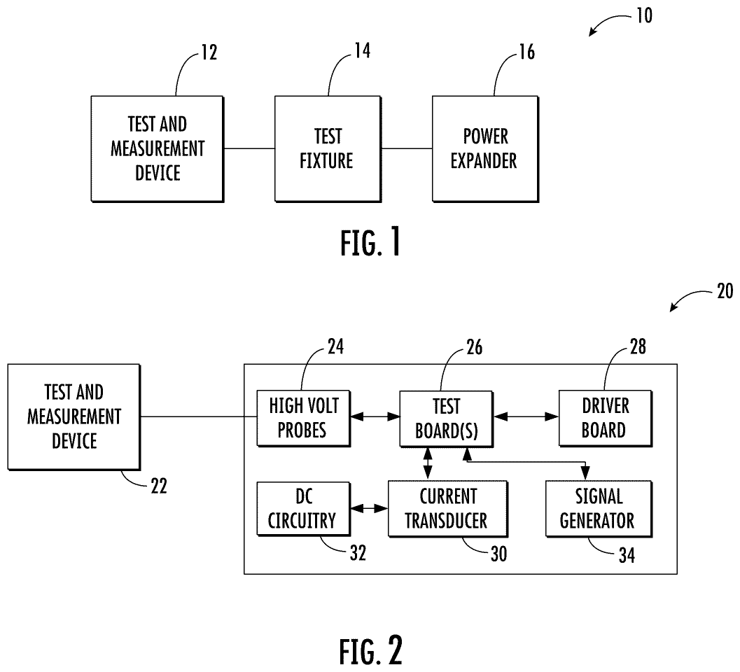

Conventionally, high power characterization of devices under test (DUTs) typically involve a static measurement platform. FIG. 1 shows an example of such a platform 10. In this example, the platform includes a test and measurement device 12, a test fixture 14 to which one or more DUTs (not shown) is connected, and a power expander 16.

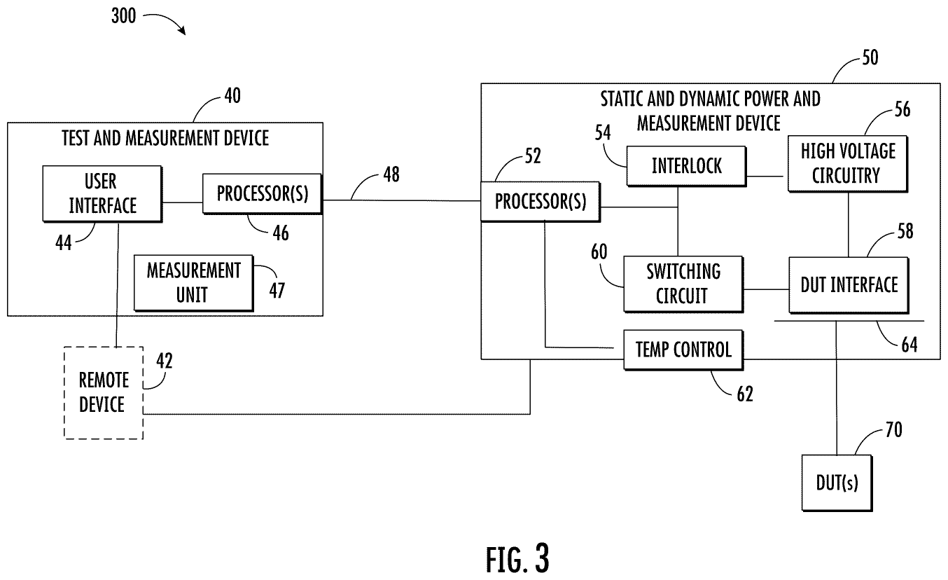

Performing dynamic power characterization requires a separate platform, which is a large floor model platform, or a custom platform. FIG. 2 shows an example of such a platform 20 that may include some or all of the components shown. A test and measurement device 22 may actually include one or more test and measurement devices, such as an oscilloscope and an impedance analyzer. The test and measurement device 22 connects to the test boards 26 and the DUT by high voltage probes 24. The test boards 26 may have a driver board 28, typically used to turn power switches ON and OFF with stability and possibly provide power protection. DC circuitry 32 may include DC-link capacitances, a DC voltage supply, and load inductors. A current transducer 30 and a signal generator 34 connect to the test boards to allow the boards to be tested.

Generally, characterizing the devices either statically or dynamically takes separate, large instrument and fixture platforms. The embodiments here provide a combined characterization system that has two components, an interactive test and measurement device such as an oscilloscope, impedance analyzer, combination of both, or one or more of many other test and measurement devices. For simplicity, this discussion will refer to this testing component as a test and measurement device. The other component is a power delivery and measurement front end with a DUT interface for mounting the test boards, which this disclosure may also refer to as the fixture. The embodiments here generally involve two separate components, but they could also be mounted into one housing.

As used here, the term “high voltage” refers to any voltage including and above 42 volts.

The embodiments here provide a dual-purpose characterization platform with several advantages. The system, meaning both the testing device and the fixture, is sized to allow transportation by one individual. The fixture encloses all the high voltage circuitry for safety and may have an interlock that prevents improper operation of high voltage systems that may result from faults in the system. The system simplifies setup in that the user only needs to put the DUT into the fixture. The two components in the system connect by a simple cable, so the system does not require re-cabling between various tests. Automated switching of the measurement configuration allows the user to obtain all the desired parameters for the tests. The fixture may also include heating and/or cooling equipment, and a protective barrier around the device in case of device damage.

FIG. 3 shows an embodiment of a test and measurement system 300, which may also be referred to as a platform, having a test and measurement device 40 such as an oscilloscope or other test and measurement device. For case of discussion, the device 40 may be referred to as a test and measurement device. The other part of the system is a static and dynamic power and measurement device 50. These terms are not intended to limit the capabilities of either device, so no such limitation should be implied.

The test and measurement device 40 may have many different components, including a user interface 44 that allows a user to interact with various menus. The user interface 44 allows the user to make selections as to the tests to be run, set parameters, etc., such as through a display having a touch screen or various buttons and knobs. The test and measurement device 40 has one or more processors 46 that receive the user inputs and send the parameters and other selections to the measurement device and may receive output from the power and measurement device 50 and generate outputs for the user from the data. The test and measurement device 40 includes a measurement unit 47 that performs tests and measures parameters of a DUT. A remote device 42, such as a computing device such as a personal computing device or smart phone, may also access the test and measurement system 300 for remote operation, either through the test and measurement device 40 or the power and measurement device 50. The term “processor” as used here means any electronic component that can receive an instruction and perform an action, such as microcontrollers, field programmable gate arrays (FPGA), and application-specific integrated circuits (ASIC), as will be discussed in more detail below.

The test and measurement device 40 communicates with the power and measurement device 50 through a direct connection 48, such as a cable. The two measurement devices 40, 50, and the direct connection 48, are configured to be portable, transportable by one individual. The direct connection 48 connects to each device through connection circuitry (not shown) that allows the measurement devices 40, 50 to switch test configurations without having to re-cable.

The power and measurement device 50 may also have several different elements. These may include one or more processors 52, high voltage circuitry 56 that provides high voltage to one or more device under test (DUT(s)) 70, and an interlock 54 that acts as protection for the high voltage circuitry. The DUT(s) 70 may include one or more separate DUTs, depending on a test configuration of the test and measurement device 40 and power and measurement device 50. The interlock 54 is designed to prevent device damage for any dangerous conditions resulting from the high voltage produced by the high voltage circuitry 56. The DUT(s) 70 mounts to a DUT interface 58, which may be a universal DUT interface to which the DUT is mounted and that allows the DUT(s) 70 to connect to the various components in the power and measurement device 50.

Operation of the high voltage circuitry 56 as well as the operation of the DUT(s) 70 may generate heat, and/or the DUT(s) 70 may need a particular temperature range to operate. The power and measurement device 50 accordingly may include temperature control circuitry 62 to control the temperature of the DUT(s) 70. The one or more processors 52 monitor the temperature and operate the temperature control circuitry 62 which may comprise items such as fans, switchable heat sinks, cooling systems, heaters, etc. The power and measurement device 50 may also include a barrier 64 to protect the power and measurement device 50 from damage by the DUT(s) 70. The power and measurement device 50 may also include a switching circuit 60, which controls operation of various components within the power and measurement device 50 to test and measure characteristics of the DUT(s) 70.

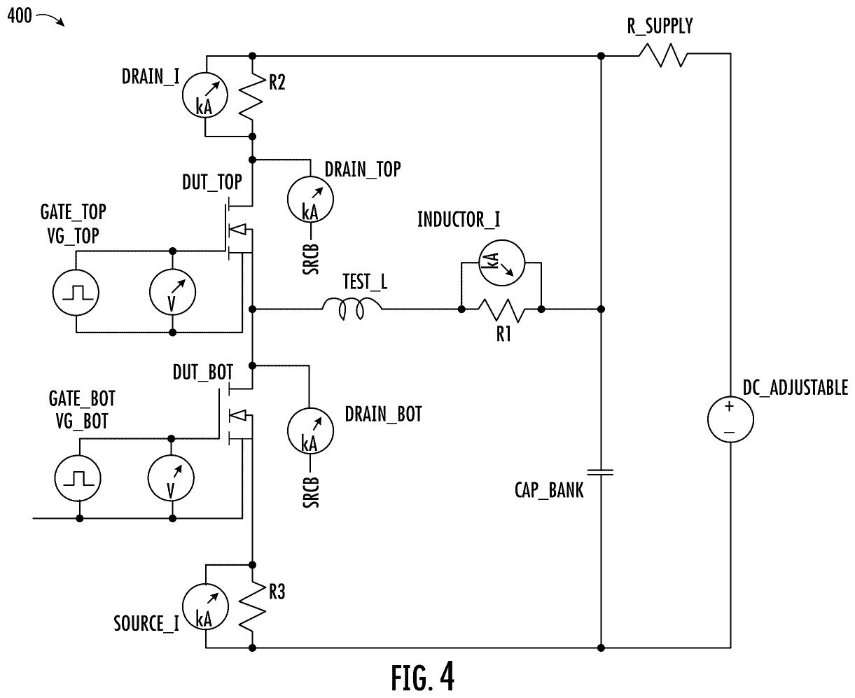

Generally, in operation, the user supplies an input through the user interface 44, remotely or directly, to control operation of the power and measurement device 50 to characterize the DUT(s) 70 either statically or dynamically. Typically, dynamic characterization is accomplished using a half bridge circuit such as in the characterization circuit 400 in the embodiment shown in FIG. 4. In general, the characterization circuit 400 is housed within the power and measurement device 50, and more specifically within the switching circuit 60, although embodiments of the disclosure are not limited to such an example.

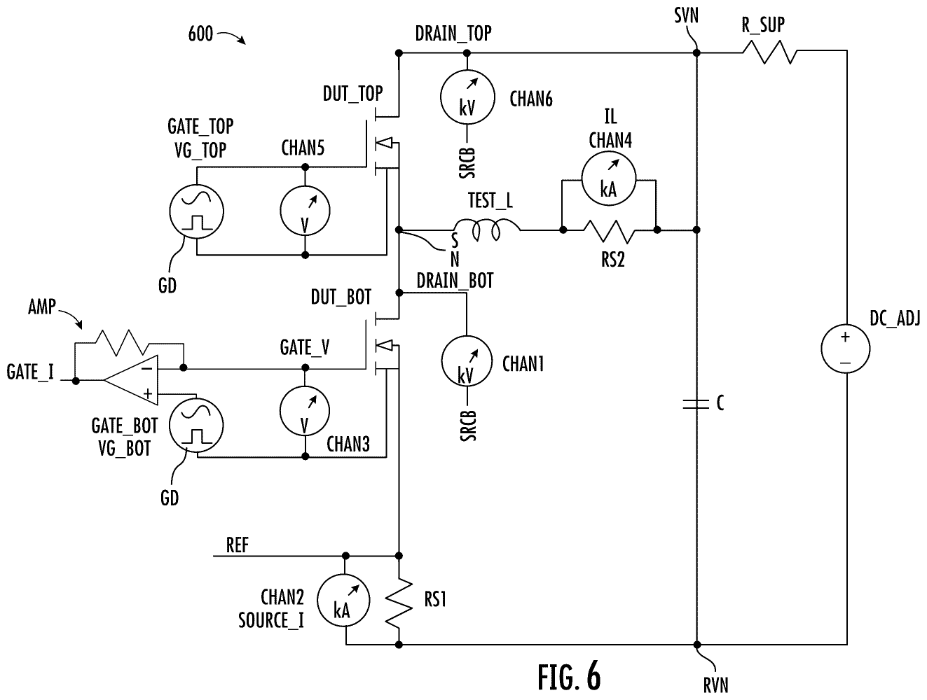

The characterization circuit 400 includes a half bridge circuit formed by two DUTs DUT_top and DUT_bot, which correspond to the DUT(s) 70 illustrated in the test and measurement system 300 of FIG. 3. The DUT DUT_top may be referred to as the top device DUT_top and the DUT DUT_bot referred to as the bottom device DUT_bot in the present description. One method of performing dynamic characterization, referred to here as the double pulse method, uses a half bridge circuit. The double pulse method or “double pulse testing” is discussed in more detail below with reference to FIG. 6. In the characterization circuit 400, the top device DUT_top and bottom device DUT_bot of the half bridge circuit are coupled in series between a supply voltage node and reference voltage node. Each of the devices DUT_bot, DUT_top is a field-effect transistor (FET) in the example embodiment of FIG. 4, and more specifically an N-channel MOSFET.

In general operation, the bottom device DUT_bot is turned ON to obtain a desired current through a test inductor Test_L. Subsequently, the bottom device DUT_bot is turned OFF and the top device DUT_top is turned ON, which circulates the inductor current from the Test_L inductor through the top device DUT_top. Alternatively, the top device DUT_top may be replaced by a diode if only one DUT(s) 70 is being tested. After a specified time that depends upon characteristics of the top and bottom devices DUT_top, DUT_bot, the top device DUT_top is turned OFF, and the bottom device DUT_bot is again turned ON. Desired data to test and characterize the top and bottom devices DUT_top, DUT_bot may be collected during these transitions and operation of the top and bottom devices DUT_top, DUT_bot, and energy losses may be calculated. This same platform, depending upon the control of voltages and currents through the devices DUTs DUT_top, DUT_bot, can be used to extract static parameters.

Replacing the top device DUT_top with a diode or a short allows gate control of the bottom device DUT_bot which, in turn, allows extraction of static current-voltage (I/V) curves. With the top device DUT_top available or present, additional methods of extracting static data can be used. These may include independent gate/drain pulsing of potentials at the bottom device DUT_bot. To do so, the system would control the voltage at the gate of the bottom device DUT_bot to allow proper transfer characteristics measurements of the device. Static I/V device characterizations do not need the test inductor Test_L, but the inclusion or presence of the test inductor Test_L allows the same circuit to perform both static and dynamic characterizations. If both top and bottom devices DUT_top, DUT_bot are present in the characterization circuit 20, and are the same types of device, the maximum power would be split between the top and bottom devices DUT_top, DUT_bot. If a full power test of one of the devices DUT_top, DUT_bot is desired, the other device would be replaced with a short.

FIG. 4 also shows a number of measurement points or channels in the characterization circuit 400 at which the power and measurement device 50 detects or senses electrical parameters, namely voltages or currents, of the top and bottom devices DUT_top, DUT_bot during testing and characterization of these devices DUT_top, DUT_bot. Each measurement channel is indicated with an angled arrow and an associated descriptor indicating the parameter being sensed at that measurement channel. For example, the characterization circuit 400 includes a first current sense resistor R1 coupled in series with test inductor Test_L and second and third current sense resistors R2, R3 coupled in series with the top and bottom devices DUT_top, DUT_bot as shown. A measurement channel detects a current through the resistor R1, which corresponds to current Inductor_i through the test inductor Test_L. Another measurement channel detects current through resistor R2, which corresponds to drain current Drain_i into top device DUT_top. A third measurement channel detects current through resistor R3 that corresponds to source current Source_i through bottom device DUT_bot.

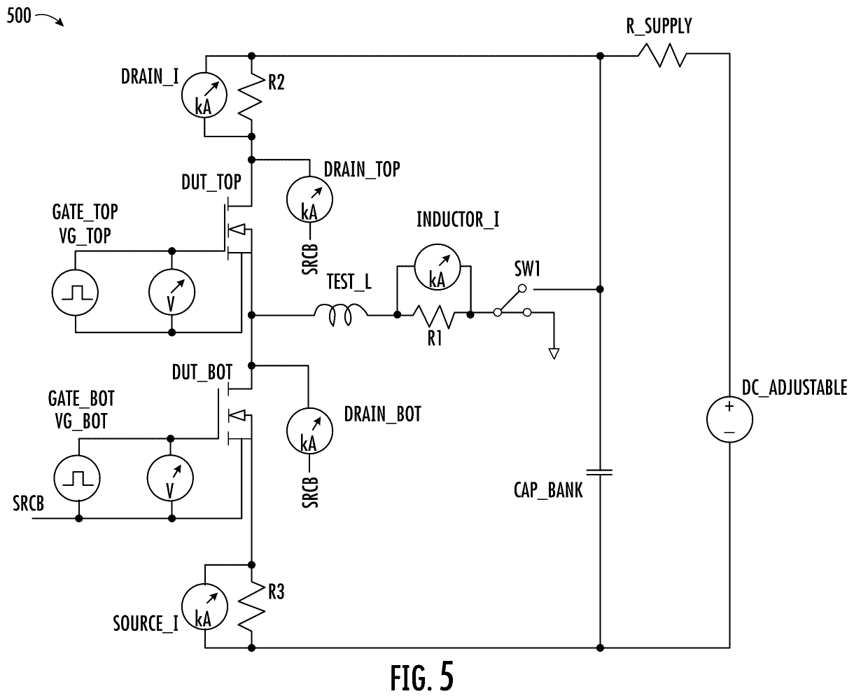

The characterization circuit 400 includes additional measurement channels for detecting voltages and currents at various points in the characterization circuit, with all the measurement channels enabling the power and measurement device 50 to capture operational data for the top and bottom devices DUT_top, DUT_bot and utilize this captured operational data to perform characterization of one or both of the top and bottom devices DUT_top, DUT_bot. Similar measurement channels are shown in the schematic diagrams of FIGS. 5-8 and will not be discussed in more detail in relation to these figures as the function of these test points or channels will be understood from the above description of measurement channels in relation to FIG. 4.

FIG. 5 shows an embodiment of a characterization circuit 500 including a half bridge switching circuit formed by a top device DUT_top and bottom device DUT_bot, and that includes a switch SW1 used to allow selection between the top and bottom devices DUT_top, DUT_bot. The selection may come into the power and measurement device 50 (FIG. 3) through user interface 44 on the test and measurement device 40 of FIG. 3, with the selection being passed to the power and measurement device 50 through direct connection 48. With the addition of switch, SW1, if both the top and bottom devices DUT_top and DUT_bot are installed, both DUT_top and DUT_bot can be characterized in static and dynamic configurations. The configuration of the characterization circuit 500 shown in FIG. 5 shows the selection of the bottom device DUT_bot for testing or characterization. In operation, the user selects static or dynamic characterization, as well as the selection of one of the top and bottom devices DUT_top, DUT_bot through the user interface 44 on the test and measurement device 40 in the test and measurement system 300 of FIG. 3. The one or more processors 46 of the test and measurement device 40 then sends the selections and any other parameters to the power and measurement device 50. The one or more processors 52 in the power and measurement device 50 will then provide signals to the switching circuit 60 to appropriately set switch SW1.

Embodiments of test and measurement systems according to the disclosure include one or both of the characterization circuits 400, 500 of FIGS. 4 and 5 and provide the ability to combine static and dynamic measurements without the need to use multiple setups and instruments, or even the need to re-cable a particular configuration. The test and measurement systems output desired characterization data for DUTs being tested or characterized. This data may be produced on the user interface 44 of the test and measurement device 40, and/or may be output to a file for further analysis such as a file for an analysis software package. This may be accomplished by the one or more processors 46, 52 in either the power and measurement device 50 or the test and measurement device 40.

Embodiments of the present disclosure are directed to characterization circuits for test and measurement systems that eliminate the need for conventional bias tees to perform static and dynamic characterization of DUTs. As described in more detail below, the solid-state bias tec includes a DUT and a gate drive voltage generator that provides a DC pulse signal and an AC signal to the gate of the DUT to cause this DUT to provide required current and voltage signals to another DUT that is being characterized. The characterization circuit operates in different modes, which enables the functionality of the DUT in the solid-state bias tee and a DUT being characterized to be reversed and, in this way, enable dynamic and static characterization of both DUTs without the use of conventional bias tees. Eliminating the need for conventional bias tees is advantageous as such conventional bias tees must be designed for specific voltage and frequency ranges and typically include discrete inductive, capacitive, and resistive components, which complicates integration of the conventional bias tees into a dynamic characterization platform. Conventional bias tees also have current and frequency limitations that limit the impedance measurements that may be performed on the DUT being characterized. Further embodiments of the disclosure are directed to characterization circuits coupled to first and second DUTs that can generate, at the same time, the gate charge characterization parameters for one the DUTs and body diode characterization of the other DUT.

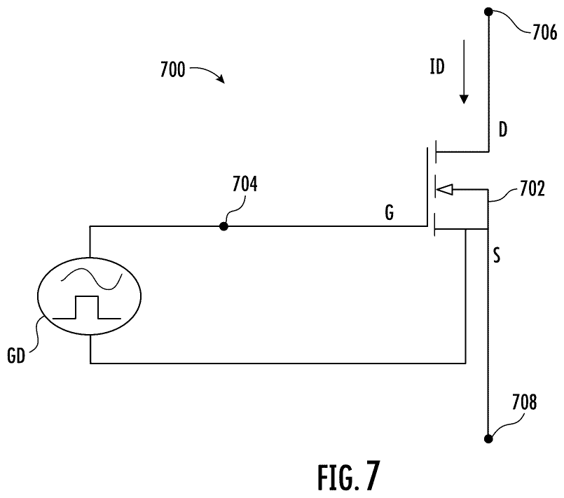

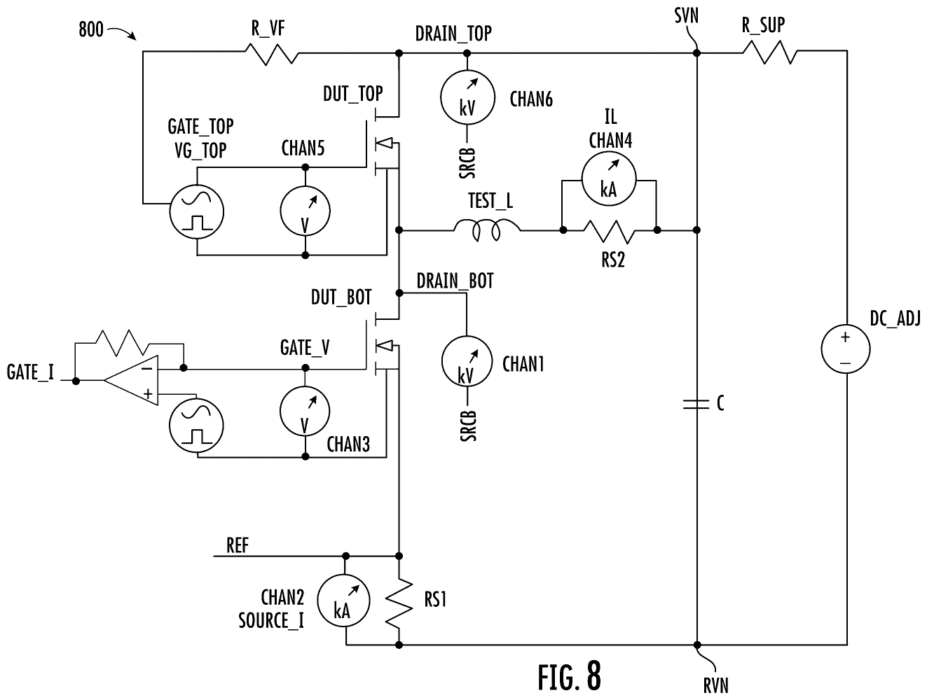

FIG. 6 is a schematic diagram of an example characterization circuit 600 for static and dynamic characterization of one or more DUTs DUT_top, DUT_bot in conjunction with the test and measurement system 300 of FIG. 3 according to embodiments of the disclosure. The characterization circuit 600 enables both static and dynamic characterization of the DUTs DUT_top and DUT_bot, which may once again be referred to as top device DUT_top and bottom device DUT_bot with reference to FIG. 6 as well as with reference to DUTs in FIGS. 7 and 8 in the following description. Each of the top and bottom devices DUT_top, DUT_bot is an N-channel MOSFET in the example embodiment of FIG. 6. Further embodiments may include other types of power transistors. Each DUT will be described as including a drain, source, and gate node, which applies to embodiments where each DUT is a MOSFET, but these nodes are intended to apply to equivalent nodes associated with different types of transistors as well.

In the characterization circuit 600 FIG. 6, the top device DUT_top and bottom device DUT_bot form a half bridge circuit coupled in series with a current sense resistor RS1 between a supply voltage node SVN and a reference voltage node RVN. An adjustable DC supply voltage source DC_adj having a supply resistance R_sup is coupled across the voltage nodes SVN, RVN to supply a desired DC voltage across these nodes. A capacitor C, which may include one or more capacitors, filters noise across the voltage nodes SVN, RVN.

A switching node SN is defined at the interconnection between the source and drain of the top and bottom devices DUT_top, DUT_bot and a test inductor TEST_L is coupled in series with a current sense resistance RS2 between the switching node SN and the supply voltage node SVN. The test inductor TEST_L enables the characterization circuit 600 to provide, through one of the top and bottom devices DUT_top, DUT_bot acting as a source element, a desired current through or voltage across the other one of the top and bottom devices DUT_top, DUT_bot as part of dynamically characterizing the other one of the top and bottom devices DUT_top, DUT_bot. The one of the top and bottom devices DUT_top, DUT_bot being characterized may also be referred to as a measured element in the present description. A gate drive voltage generator GD operates in combination with an amplifier AMP to supply a gate drive signal including a DC pulse and AC signal to the bottom device DUT_bot, and to detect a gate current of the bottom device DUT_bot as part of measuring a gate-to-source capacitance Cgs of the bottom device DUT_bot.

FIG. 6 shows the configuration of the characterization circuit 600 where the top device DUT_top is functioning as the source element and the bottom device DUT_bot is the measured element (i.e., the device being characterized). The top and bottom devices DUT_top and DUT_bot are controlled so that desired AC and DC voltages are applied to the bottom device DUT_bot to measure desired dynamic and static parameters of the bottom device DUT_bot and thereby characterize the bottom device DUT_bot. Static current and voltage device characterizations of the devices DUT_top, DUT_bot do not need the test inductor Test_L, but the presence of the inductor allows the same characterization circuit 600 to perform both static and dynamic characterizations. In operation, the top device DUT_top is initially turned OFF bottom device DUT_bot is initially turned ON to provide a desired inductor current IL as a desired drain current through the bottom device DUT_bot. The bottom device DUT_bot is turned OFF when the current through the test inductor TEST_L reaches a desired value, and the inductor current IL recirculates through a body diode (not shown) of the top device DUT_top. The gate drive generators GD supply DC and AC signals to the devices DUT_bot, DUT_top that enable static parameters of the bottom device DUT_bot to be measured, as well as dynamic parameters like gate-to-source capacitance Cgs, gate-to-drain capacitance Cgd, and drain-to-source capacitance Cds.

The characterization circuit 600 may characterize each of the top and bottom devices DUT_top, DUT_bot by switching connection of the test inductor TEST_L and switching coupling of the amplifier AMP. To configure the bottom device DUT_bot as the source element and the top device DUT_top as the measured element being characterized, the terminal of the test inductor TEST_L that is coupled to the supply voltage node SVN would instead be coupled to the reference voltage node RVN. In addition, the amplifier AMP would be coupled to the gate of the top device DUT_top in the same way as shown for the bottom device DUT_bot in FIG. 6, or, alternatively, the characterization circuit 600 may include an additional amplifier (not shown) coupled to the gate of the top device DUT_top.

The characterization circuit 600 includes a number of measurement points or channels Chan1-Chan6 at which the power and measurement device 50 detects or senses electrical parameters, namely voltages or currents, of the top and bottom devices DUT_top, DUT_bot during testing and characterization of these devices. Through sensing parameters at the measurement channels Chan1-Chan6 the power and measurement device 50 captures operational data for the one of the top and bottom devices DUT_top, DUT_bot that is being characterized. The power and measurement device 50 utilizes this captured operational data to characterize the corresponding device DUT_top, DUT_bot. The first measurement channel Chan1 senses a drain voltage Drain_bot of the bottom device DUT_bot relative to a reference voltage node srcB. A drain current through the bottom device DUT_bot is sensed through measurement point Chan2 while a gate-to-source voltage Vgs of the bottom device DUT_bot is sensed at measurement channel Chan3. The measurement channel Chan4 measures an inductor current IL through the test inductor TEST_L, test channel Chan5 measures the gate-to-source voltage Vgs of the top device DUT_top, and test channel Chan6 measures the drain voltage Drain_top of the top device DUT_top.

In the characterization circuit 600, one of the devices DUT_top, DUT_bot may be configured to realize the equivalent operation of a source bias tee during double pulse testing. Double pulse testing is a testing methodology that measures dynamic characteristics, such as switching parameters, of power switching elements like power FETs. The top device DUT_top is the source element and functions as the equivalent of a source bias tee in the configuration of FIG. 6. In this configuration, the top device DUT_top provides required DC voltages as well as a necessary AC signal to properly stimulate the measured element, which in this situation is the bottom device DUT_bot being characterized.

The embodiment of FIG. 6 shows the configuration for current mode drive of the top device DUT_top through modulation of the gate-to-source voltage Vgs of this device. In this way, the top device DUT_top functions as the source element for characterization of the bottom device DUT_bot. Due to the squared relationship between the gate-to-source voltage Vgs and the drain current ID of the top device DUT_top where the top device DUT_top is an FET (i.e., ID=f (Vgs2)), the AC signal component provided by the gate drive voltage generator GD is generally provided at half the desired measurement frequency. A drain current ID at twice the frequency of the AC signal component applied on the gate results due to the frequency doubling resulting from this squaring of the AC signal component. This AC signal component generates an AC signal superimposed on a DC bias current (i.e., drain current ID through device DUT_bot). Impedance measurements of the bottom device DUT_bot to determine the gate-to-source capacitance Cgs and drain-to-source capacitance Cds are made by vector division of an imposed AC voltage provided by the top device DUT_top on the drain (Drain_bot) of the bottom device DUT_bot as measured by channel Chan1, and measuring AC current Gate_i of the bottom device DUT_bot as provided by the amplifier AMP as well as the source current (Source_i) of the bottom device DUT_bot as measured at channel Chan2.

In the characterization circuit 600, the top device DUT_top may be utilized as a controlled current source for characterization of the bottom device DUT_bot at a specified drain current ID through the bottom device DUT_bot. In addition, the top device DUT_top may be utilized to set a specified voltage on drain (Chan1) of the bottom device DUT_bot. In embodiments of the characterization circuit 600, the use of the top device DUT_top as a controlled current source or to set a specified drain voltage may be controlled in a swept or pulsed mode manner to measure characteristics of the bottom device DUT_bot over a wide range of specified parameters. The value of the current or voltage being controlled may be swept or varied over a range of values and pulsed in instances where applying a DC signal at the desired value could destroy or damage the bottom device DUT_bot being characterized.

The gate drive voltage generators GD driving the gates of the top and bottom devices DUT_top, DUT_bot provide the characterization circuit 600 the capability to enable characterization of both the top and bottom devices DUT_top, DUT_bot. Moreover, the capability of measuring gate and source currents of each of the top and bottom devices DUT_top, DUT_bot relative to AC signals applied across the drain of the bottom device DUT_bot (i.e., of the DUT being characterized) enables measurement of all impedances associated with the bottom device DUT_bot. These measurement capabilities and the capability of switching the source and measuring elements the characterization circuit 600 to fully characterize each of the top and bottom devices DUT_top, DUT_bot.

FIG. 7 is a schematic of a solid-state bias tee 700 that may be utilized in the characterization circuits 600, 800, and 900 of FIGS. 6, 8 and 9 according to embodiments of the disclosure. The solid-state bias tec 700 may be utilized in other characterization circuits, including those that are not configured to perform double pulse testing, as well as the characterization circuits 600, 800 and 900. The solid-state bias tee 700 includes an FET 702 and a gate drive voltage generator GD that provides a DC pulse signal and an AC signal to the gate of the FET 702. The FET is an N-channel FET in the example embodiment of FIG. 7 but may be other types of transistors in further embodiments. The bias tee 700 includes a first node 704, second node 706, and third node 708 coupled to the gate, drain, and source, respectively, of the FET 702. In operation, the gate drive voltage generator GD supplies a drive signal on the first node 704 including suitable AC and DC pulse components to control the FET 702 function as a controlled current source to provide a desired drain current ID or to set a specified voltage on the source of the FET 702. In this way, the gate drive voltage generator GD and FET 702 function as a bias tec to provide a desired voltage or current having desired AC and DC components at the source S of the FET 702. In the example embodiment of FIG. 6, the gate drive voltage generator GD and top device DUT_top correspond to an example implementation of the bias tec 700 of FIG. 7.

FIG. 8 is a schematic diagram of another example characterization circuit 800 for static and dynamic characterization of one or more DUTs in conjunction with the test and measurement system 300 of FIG. 3, according to embodiments of the disclosure. Components in the characterization circuit 800 that are the same as the corresponding components in the characterization circuit 600 of FIG. 6. In contrast to the characterization circuit 600, the characterization circuit 800 includes voltage feedback from the drain Drain_top through a voltage feedback resistor R_vf to control the gate drive voltage generator GD driving the gate of the top device DUT_top, with the top device DUT_top functioning as the source element in the illustrated example embodiment. In the characterization circuit 800, the frequency of the modulating or AC signal provided by the gate drive voltage generator GD is the same as the desired frequency of the drain current ID supplied to the bottom device DUT_bot being characterized.

Both the characterization circuits 600, 800 can be utilized to measure capacitances Cgd and Cds. To measure the gate-to-source capacitance Cgs, the gate drive voltage generator GD provides a proper DC bias signal to the gate of the bottom device DUT_bot as well as a desired AC stimulus signal, with the impedance being measured using the resulting gate current Gate_i sensed by amplifier AMP and gate voltage measurements at channel Chan3.

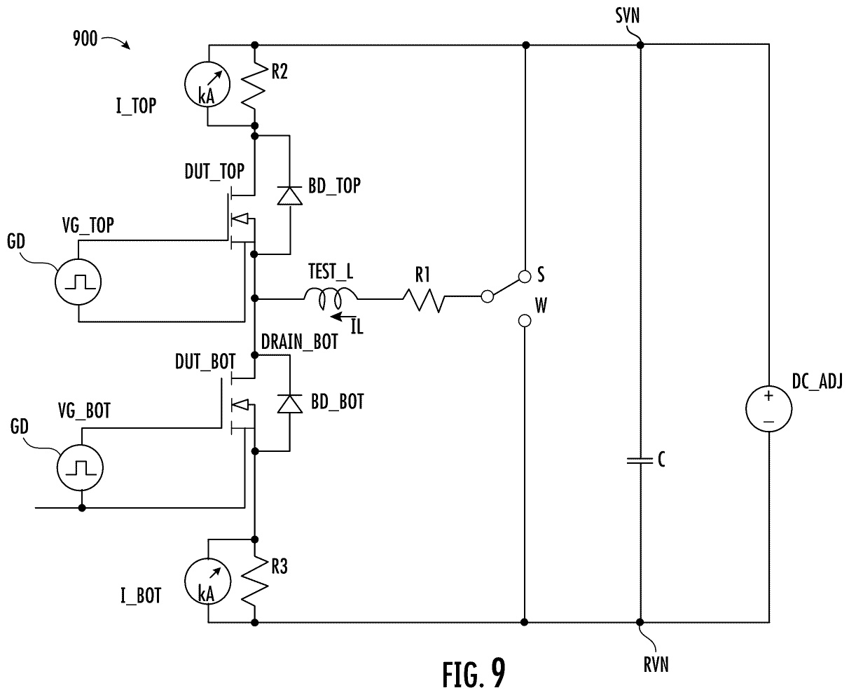

FIG. 9 is a schematic diagram of an example characterization circuit 900 for gate charge characterization and body diode characterization of one or more DUTs in conjunction with the test and measurement system 300 of FIG. 3, according to embodiments of the disclosure. Conventional approaches for measuring the gate charge curve of an FET involve a source measurement unit (SMU) or other equivalent device that supplies a constant current to the gate of the FET and measures the resulting gate-to-source voltage Vgs over time. In addition, an SMU or equivalent device supplies a desired drain voltage and drain current to the FET at the same time. This approach requires dedicated equipment in the form of the SMUs to generate the gate charge curve and provide static characterization of the FET.

The characterization circuit 900 enables gate charge curve characterization of each of a top device DUT_top and bottom device DUT_bot without recabling connections between each device and external test equipment. The top and bottom devices DUT_top, DUT_bot are coupled in series with a switching node SN defined at the interconnection of the two. A test inductor TEST_L is coupled is series with a first current sense resistor R1 between a switch SW and the switching node SN. An adjustable DC supply voltage source DC_adj is coupled across the voltage nodes SVN, RVN to supply a desired DC voltage across these nodes and a capacitor C filters noise across the voltage nodes. To measure a current I_top, I_bot through the top and bottom devices DUT_top, DUT_bot, respectively, a second current resistor R2 is coupled between the supply voltage node SVN and the drain of the top device DUT_top and a third current sense resistor R3 is coupled between the source of the bottom device DUT_bot and the reference voltage node RVN. In FIG. 9, the switch SW is shown in the position making the bottom device DUT_bot the measured element or the device being characterized and the top device DUT_top the source element.

In operation of the characterization circuit 900, the gate charge characteristic of the bottom device DUT_bot may be determined using the following process. First, the supply DC_adj is set to a desired starting DC voltage level for the drain-to-source test voltage for the bottom device DUT_bot. Initially, both the top and bottom devices DUT_top, DUT_bot are turned OFF. The bottom device DUT_bot is then turned ON for a duration of time to allow a desired inductor current IL to flow through test inductor TEST_L. The current IL through the inductor TEST_L may be calculated (di/dt=V/L) or continuously measured, with the determination then being based on either expiration of a specific time or the measured inductor current reaching a desired current threshold.

Upon the inductor current IL reaching the desired current threshold, the bottom device DUT_bot is turned OFF. At this point, inductor current IL will continue to flow through the inductor TEST_L and will also flow through the body diode BD_top of the top device DUT_top. The top device DUT_top may be turned ON at this point to reduce decay of the current IL due to losses in the body diode BD_top. A delay time is then waited to ensure the bottom device DUT_bot is sufficiently turned OFF. If the top device DUT_top is turned ON, the top device DUT_top is turned ON and then a delay time is waited to ensure before the bottom device DUT_bot is again turned ON.

At this point, the gate drive voltage generator GD provides an initial desired voltage Vg_bot on the gate of the bottom device DUT_bot. This initial voltage is typically zero voltage, but other levels might be desired. The gate drive voltage generator GD then supplies a constant current to the gate of the bottom device DUT_bot. In an embodiment, the constant current source of the gate drive voltage generator GD may be substituted with a voltage source in series with a resistor. The voltage Vg_bot at the gate of the bottom device DUT_bot is then continuously measured, or sampled, over time.

The measured gate voltage Vg_bot and the current, or a calculated current if the gate drive voltage generator GD includes a voltage source with a resistor, to obtain a full gate charge characteristic of the bottom device DUT_bot for the set drain current and starting drain voltage Drain_bot. This entire process may then be repeated, if desired, at different drain-to-source VDS voltages for the bottom device DUT_bot and at different desired levels or values of drain current ID through the bottom device DUT_bot. This process will provide gate charge parameters for the bottom device DUT_bot at different current and voltage levels. To obtain these same gate charge parameters for the top device DUT_top, the switch SW is switched to the bottom position so that the associated terminal of the test inductor TEST_L is connected to the reference voltage node RVN instead of the supply voltage node SVN. Now, if the operation of the top and bottom devices DUT_top, DUT_bot is reversed or switched from that described above, the gate charge curve characteristics of the top device DUT_top may be measured. This operation of the characterization circuit 900 to characterize gate charge parameters of both the top and bottom devices DUT_top, DUT_bot assumes that gate control and measurement capabilities of the characterization circuit is the same for is same on both the top and bottom devices DUT_top, DUT_bot.

In addition to gate charge curve parameters of the top and bottom devices DUT_top, DUT_bot, the characterization circuit 900 enables measurement of dynamic characteristics of the body diodes BD_top, BD_bot of the top and bottom devices DUT_top, DUT_bot. These body diode parameters are typically measured through double pulse testing. The characterization circuit 900 can measure body diode parameters through the following process. Initially, the adjustable DC supply voltage source DC_adj is set to a desired starting DC voltage level and both the top and bottom devices DUT_top, DUT_bot are turned OFF. The bottom device DUT_bot is then turned ON for a period of time to reach a desired current threshold for the current IL through the inductor TEST_L. As previously described, the value of the current IL may be calculated based on the time the bottom device DUT_bot is turned ON or may be continuously measured.

Once the current IL through the inductor TEST_L reaches the desired threshold, the bottom device DUT_bot is turned OFF. At this point, the inductor current IL will now flow through the body diode BD_top of the top device DUT_top. During this time, the current and voltage parameters of the body diode BD_top can be extracted during quiescent sections of the current through the body diode as well as dynamic parameters during transitions of this current. The bottom device DUT_bot is thereafter turned ON, and a delay time provide to adjust inductor current IL to the next desired value or level, with the bottom device DUT_bot thereafter being turned OFF and the body diode parameters of the body diode BD_top once again measured at the new level of the inductor current. This process is then repeated at different DC voltage levels provided by the adjustable DC supply voltage source DC_adj, with the turn ON timing of the bottom device DUT_bot being adjusted accordingly account for variation in the rate of change of the inductor current IL through the inductor IL, or measuring this current directly until a threshold is reached. The entire process may be repeated at different gate-to-source voltages Vgs supplied to the gate drive voltage generator GD coupled to the top device DUT_top.

Through the process described above, the characterization circuit 900 extracts or measures the body diode parameters of the body diode BD_top of the top device DUT_top. This process may be performed when the configuration of the switch SW is set in the first position shown in FIG. 9. To extract or measure the same parameters for the body diode BD_bot of the bottom device DUT_bot, the switch SW need merely be set to the second position, namely coupling the associated terminal of the inductor TEST_L to the reference voltage node RVN instead of the supply voltage node SVN. Once the switch SW is set to the second position, the control and measurement of the top and bottom devices DUT_top, DUT_bot described above to extract or measure parameters of the body diode BD_bot of the bottom device DUT_bot.

The characterization circuit 900 eliminates the need for a negative supply voltage source to perform complete body diode characterization for both the top and bottom devices DUT_top, DUT_bot. Moreover, in embodiments of the characterization circuit 900 the body diode parameters of one of the top and bottom devices DUT_top, DUT_bot may be measured while the gate charge curve parameters of the other device are being measured. For example, while the gate charge curve characteristics of the bottom device DUT_bot are being measured as described above, the characteristics of the body diode BD_top of the top device DUT_top may be measured during the portions of the gate charge curve characterization process when the bottom device DUT_bot is turned OFF. This extraction of parameters occurs at the same time or simultaneously during operation of the characterization circuit 900, which reduces the time required to characterize the gate charge curve for one of the devices DUT_top, DUT_bot and the body diode characteristics of the other device DUT_bot, DUT_top.

In the embodiment of FIG. 9, the top and bottom DUTs DUT_top, DUT_bot are shown as being MOSFETs that each include a corresponding body diode BD. Embodiments of the characterization circuit 900 are not, however, limited to characterizing MOSFETs or other types of FETs including body diodes such as SiC MOSFETs. More generally, the characterization circuit 900 may characterize a reverse current path in FETs that do not include a body diode, such as Gallium Nitride (GaN) FETs. In embodiments of the characterization circuit 900 where the top and bottom DUTs DUT_top, DUT_bot are FETs that do not include a body diode BD, such as GaN FETs, the characterization circuit would operate as described above except, when a reverse conduction condition of the one of the top and bottom GaN FETs being characterized is to be measured, the characterization circuit 900 would apply a desired gate voltage on the GaN FET being characterized. This desired gate voltage would be applied during the time when the inductor current IL would be expected to circulate as a reverse current through the GaN FET being characterized.

Embodiments of the present disclosure are directed to characterization circuits for test and measurement systems that used in parametric testing on wafers. As described in more detail below, the present disclosure describes a system for carrying out production-level characterization of power devices on wafers, incorporating parametric-sensitive measurements, and meeting speed requirements of production processes. The present disclosure involves a resolution to these challenges by integrating parametric systems or semiconductor characterization systems with power device measurements. The present disclosure involves a resolution to these challenges by including some pins on the probe card for low voltage and/or low current measurements and other pins for power device assessments, which may involve high voltage and/or high current measurements. The present disclosure involves a resolution to these challenges by substituting the scope with an ultra-fast pulse measure unit (PMU), allowing for short and fast voltage pulses while also measuring transients, fulfilling the role of both gate drive functionality for dynamic tests and measurement, effectively replacing a scope. A central component of the present disclosure entails employing a circuit that performs functions such as voltage clamping, voltage division, and protection against 3 kV potentials.

The integration of these components addresses the previously mentioned challenges, presenting an unparalleled and distinctive solution. This solution brings forth several distinct capabilities. For example, the PMU can serve as a test and measurement instrument within a characterization system. Customized and adaptive tests can be run using software on the characterization system, enabling data analysis and parameter extraction, including dynamic R_{DS}_{ₒₙ}, double pulse, breakdown, leakage, and threshold voltage measurements. Extracted data is subsequently transmitted to the system for comprehensive data reporting.

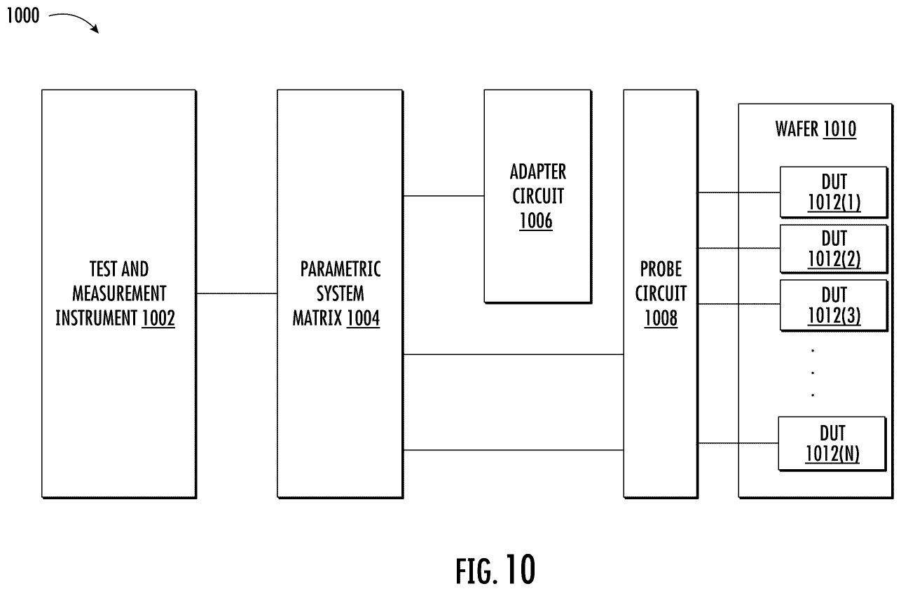

FIG. 10 shows an example of a characterization measurement platform coupled to a wafer for testing, according to some examples.

The test and measurement system 1000 includes a test and measurement instrument 1002, a parametric system matrix 1004, an adapter circuit 1006, a probe circuit 1008, and a wafer 1010. As illustrated in FIG. 10, the test and measurement instrument 1002 is coupled to the parametric system matrix 1004. The parametric system matrix 1004 is coupled to both the adapter circuit 1006 and to the probe circuit 1008. The adapter circuit 1006, in turn, is also coupled to the probe circuit 1008. The probe circuit 1008 is coupled to one or more DUTs 1012 of the wafer 1010.

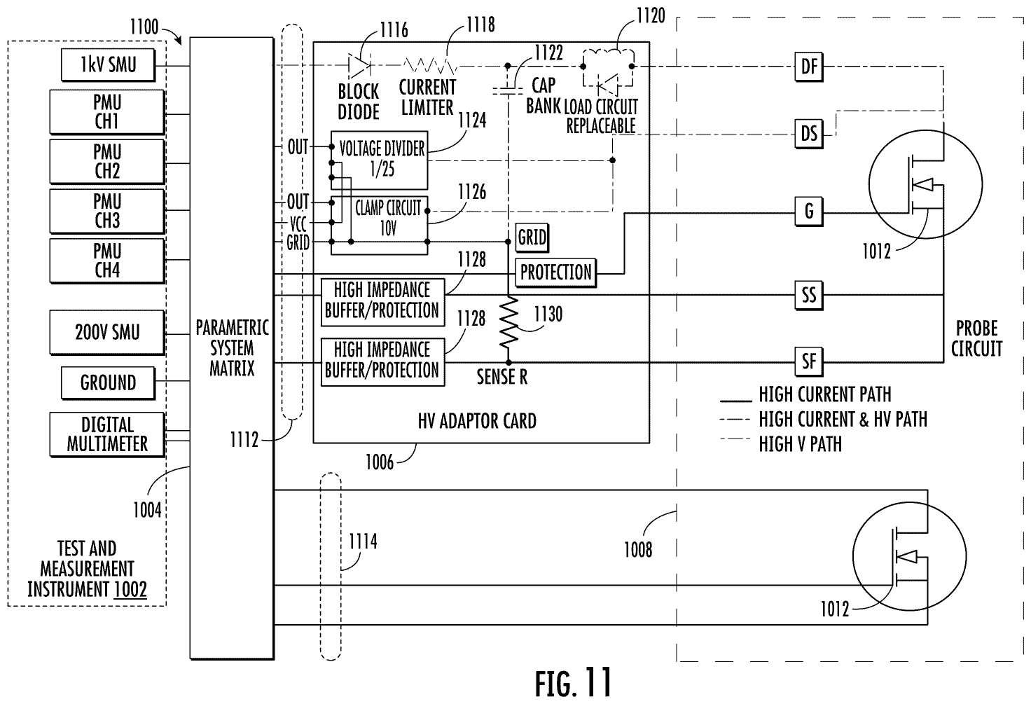

The test and measurement instrument 1002 can be any test and measurement used for testing the wafer 1010. For example, the test and measurement instrument 1002 can be a pulse measure unit (PMU), source measure unit (SMU), or a digital multimeter. In some examples, the test and measurement instrument 1002 can be the test and measurement device 12, test and measurement device 22, or test and measurement device 40. In some examples, any number of test and measurement instruments 1002 can be coupled to the parametric system matrix 1004. Further details regarding test and measurement instruments 1002 is described with reference to FIG. 11 herein.

The parametric system matrix 1004 is a switch network coupled to the test and measurement instrument 1002. In some examples, the parametric system matrix 1004 can be coupled to any number of test and measurement instruments 1002, and can be coupled to other devices, such as a ground supply. The parametric system matrix 1004 is configured to link the test and measurement instruments 1002 to the adapter circuit 1006 and in some examples, to the probe circuit 1008. Further details regarding the parametric system matrix 1004 is described with reference to FIG. 11 herein.

The adapter circuit 1006, as mentioned, is coupled between the parametric system matrix 1004 and the probe circuit 1008. In some examples, the adapter circuit 1006 comprises features of the characterization circuit 400, characterization circuit 500, characterization circuit 600, characterization circuit 800, or characterization circuit 900. The adapter circuit 1006 can be any circuit used to characterize the DUTs 1012 of the wafer 1010. Further details regarding the adapter circuit 1006 is described with reference to FIG. 11 herein.

The probe circuit 1008, as mentioned, is coupled between the adapter circuit 1006 and the wafer 1010. In some examples, the probe circuit 1008 can be the DUT interface 58. The probe circuit 1008 can be any circuit used to couple the adapter circuit 1006 and/or the outputs 1114 of the parametric system matrix 1004 to the DUTs 1012 of the wafer 1010. Further details regarding the probe circuit 1008 is described with reference to FIG. 11 herein.

The wafer 1010 may include any number of DUTs 1012. In some examples, the DUTs can be transistors. The DUTs 1012 of the wafer 1010 may comprise all the same type of power device, and in other cases, the DUTs 1012 of the wafer 1010 may comprise multiple types of power devices. In some examples, the probe circuit 1008 is coupled to any number of DUTs 1012 on the wafer 1010. The DUTs 1012 of the wafer 1010 as described in the present disclosure are not diced or packaged, but instead, the present disclosure involves testing the DUTS 1012 prior to dicing and packaging the DUTs 1012.

FIG. 11 shows an embodiment of a test and measurement system, according to embodiments of the disclosure. Specifically, FIG. 11 provides further details and examples of the characterization measurement platform coupled to a wafer for testing, according to some examples. While the test and measurement system 1100 of FIG. 11 illustrates two DUTs 1012 on the wafer 1010 of FIG. 10, the test and measurement system via the probe circuit 1008 is coupled to the DUTs 1012 and the wafer 1010, despite not being illustrated as such in FIG. 11.

As illustrated in FIG. 11, the parametric system matrix 1004 is coupled to test and measurement instruments 1002. The test and measurement instruments 1002 include but are not limited to PMUs, SMUs, ground supplies, and digital multimeters. Accordingly, the parametric system matrix 1004 comprises inputs for the one or more test and measurement instruments 1002. The parametric system matrix 1004 also comprises outputs 1112, 1114 coupled the adapter circuit 1006 and in some examples, to the probe circuit 1008. In some examples, the parametric system matrix 1004 is configured to output signals from at least one of the test and measurement instruments 1002. For example, the parametric system matrix 1004 is configured to provide first set of signals from one test and measurement instrument 1002 to outputs 1112 coupled to the adapter circuit 1006, and to provide a second set of signals from another test and measurement instrument 1002 to outputs 1114 coupled to the probe circuit 1008. Accordingly, in such example, the test and measurement system 1000 can perform multiple tests simultaneously. While the test and measurement system 1000 shows the parametric system matrix 1004 coupled only one adapter circuit 1006 and to only one other DUT 1012 via outputs 1112, 1114 respectively, the test and measurement system 1000 can include any number of adapter circuits 1006 and any number of outputs 1112, 1114 to test any number of DUTs 1012 on the wafer 1010.

The adapter circuit 1006, as mentioned, is coupled between the parametric system matrix 1004 and the probe circuit 1008. The adapter circuit 1006 includes a voltage divider 1124, a clamping circuit 1126, and at least one buffer circuit 1128. In some examples, the adapter circuit 1006 further includes a block diode 1116, a current limiter 1118, a replaceable load circuit 1120, a capacitor bank 1122, and a sense resistor 1130. As illustrated in FIG. 11, the adapter circuit 1006 includes inputs that are coupled to the outputs 1112 of the parametric system matrix 1004, and the inputs of the adapter circuit 1006 couple the outputs of the parametric system to the block diode 1116, the voltage divider 1124, the clamp circuit 1126, and the buffer circuit 1128. The block diode 1116 is in turn coupled to the current limiter 1118, and the current limiter 1118 is coupled to the replaceable load circuit 1120 and to the capacitor bank 1122. The replaceable load circuit 1120 is coupled to an output of the adapter circuit 1006. In some examples, the replaceable load circuit 1120 comprises an inductor and a diode. In other examples, the replaceable load circuit 1120 can include other components that the capacitor bank 1122 is coupled to the sense resistor 1130 and to the clamp circuit 1126. The sense resistor 1130 is coupled to an output of the adapter circuit 1006 and to a buffer circuit 1128. The voltage divider 1124 of the adapter circuit 1006 is coupled to the clamp circuit and to an output of the adapter circuit 1006. As mentioned, the clamp circuit 1126 is coupled to the input of the adapter circuit 1006, to the voltage divider 1124, and to the sense resistor 1130, and the clamp circuit 1126 is coupled to an output of the adapter circuit 1006. The buffer circuit 1128, as mentioned is coupled to the sense circuit, and is also coupled to an output of the adapter circuit 1006. In some examples, the adapter circuit 1006 also includes another buffer circuit 1128, which is coupled between an input of the adapter circuit 1006 and an output of the adapter circuit 1006. In some examples, the adapter circuit 1006 includes a path between an input of the adapter circuit 1006 directly to an output of the adapter circuit 1006.

In some examples, the buffer circuit 1128 of the adapter circuit 1006 provides protection for high voltage. For example, the buffer circuit 1128 of adapter circuit 1006 can protect against 3 kV potentials. In further examples, the buffer circuit 1128 can provide protection for high voltage by providing high impedance. In some examples, the voltage divider 1124 of the adapter circuit 1006 divides the incoming voltage from the outputs 1112 of the parametric system matrix 1004 into a smaller voltage for testing the DUT 1012. For example, the voltage divider 1124 feeds high voltage from the drain (1 kV) to a PMU, which can measure up to 40V, and thus the voltage divider 1124 divides the high voltage from the drain by a factor of 25 to feed the PMU. In some examples, the clamp circuit 1126 is configured to clamp a voltage coming into the clamp circuit 1126, and in such examples, the clamp circuit 1126 can clamp the voltage based on predetermined conditions. For example, the clamp circuit 1126 clamps the voltage at 30V.

In some examples, the clamp circuit 1126 of the adapter circuit 1006 is coupled to a GND supply and provides the GND supply to remaining circuitry inside the adapter circuit 1006. In such examples, the test and measurement system 1100 comprises a high current and low voltage path between a terminal of the DUT 1012, through the probe circuit 1008, and through the sense resistor 1130 to the GND supply in the adapter circuit 1006. Similarly, in some examples the test and measurement system 1100 comprises a high current and high voltage path between a terminal of the DUT 1012, through the probe circuit 1008, through the replacement load circuit 1120, and through the capacitor bank 1122 to the GND supply in the adapter circuit 1006. In some examples, the test and measurement system 1100 comprises a high voltage path between a terminal of the DUT 1012 to the voltage divider 1124 and to the clamp circuit 1126 of the adapter circuit 1006. In some examples, the test and measurement system 1100 also includes a high voltage path from one of the outputs 1112 of the parametric system matrix 1004 coupled to the block diode 1116, through the block diode 1116, through the current limiter 1118, to the node between the replaceable load circuit 1120 and the capacitor bank 1122.

The probe circuit 1008 comprises inputs coupled to the adapter circuit 1006 and to outputs 1114 of the parametric system matrix 1004. The probe circuit 1008 comprises ports and/or connections that are configured to be coupled to the DUTs 1012 of the wafer 1010. The signal paths of the probe circuit 1008 allow for connection of the test and measurement system 1100 to the DUTs 1012 for testing. For example, the probe circuit 1008 allow for the connection of outputs 1114 of the parametric system matrix 1004 to the terminals of the DUT 1012. Similarly, the probe circuit 1008 allows for the connection of outputs of the adapter circuit 1006 to the terminals of the DUT 1012.

In some examples, the DUT 1012 has a terminal coupled to terminal DF and terminal DS of the probe circuit 1008. The DUT includes a terminal coupled to terminal G of the probe circuit 1008, and a terminal coupled to terminal SS and terminal SF of the probe circuit 1008.

The test and measurement system 1100 as described herein can be used to perform various tests on the DUT 1012 located on the wafer 1010. As mentioned previously, the wafer 1010 has not been diced or packaged, and so the probe circuit 1008 couples directly to the DUT 1012 on the wafer 1010. Depending on the test to be applied to the DUT 1012, the test and measurement instrument 1002 works through the parametric system matrix 1004 and the adapter circuit 1006 to perform the test on the DUT 1012. Tests can include tests that determine dynamic R_{DS}_{ₒₙ}, double pulse, breakdown, leakage, and threshold voltage measurements. The tests performed on the DUT 1012 are tests that comply with Joint Electron Device Engineering Council (JEDEC) standards.

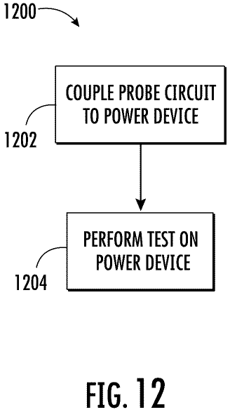

FIG. 12 is a flowchart of testing a power device on a wafer using the test and measurement system of FIG. 11, according to some examples. The flowchart shows a process 1200 having operations 1202 and 1204. Operations 1202 of process 1200 involves coupling a test and measurement system (e.g., test and measurement system 1100 of FIG. 11) to a DUT (e.g., DUT 1012) of a wafer (e.g., wafer 1010). In some examples coupling the test and measurement system to the DUT involves coupling the probe circuit of the test and measurement system to terminals of the DUT.

Operations 1204 of process 1200 involves performing a test using the test and measurement system on the DUT. As mentioned previously, the DUT to which the test and measurement system is coupled is not separate from the rest of the wafer. That is, the DUT has not been diced or packaged, and thus when performing any tests on the DUT, the test and measurement system needs to be careful about applying test signals to the DUT being tested without affect other devices on the wafer. Tests can include tests that determine dynamic RDSon′ double pulse, breakdown, leakage, and threshold voltage measurements.

The present disclosure involves integrating parametric systems and/or semiconductor characterization systems with power device measurements. The present disclosure also involves including specialized pins on the probe circuit for low voltage and/or low current measurements and other pins for power device assessments. In some examples, the probe circuit comprises at least two low-current and low-voltage input pins. The present disclosure involves substituting a scope with a PMU sourced from a characterization system, which allows for rapid voltage transient forcing and measuring, which fulfills the role of both gate drive functionality for dynamic tests and measurement.

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid-state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

### Examples

Illustrative examples of the disclosed technologies are provided below. An embodiment of the technologies may include one or more, and any combination of, the examples described below. A

Example 1 is a system for characterizing a power device, including: a parametric system matrix coupled one or more test and measurement instruments; an adapter circuit coupled to the parametric system matrix, the adapter circuit including a voltage clamping circuit coupled to the parametric system matrix; and a probe circuit coupled to the adapter circuit and to the power device, where the power device is located on a wafer.

Example 2 is the system of Example 1, where the parametric system matrix is coupled to the probe circuit.

Example 3 is the system of Example 1 or Example 2, where the wafer may include a plurality of power devices, and the power device is one of the plurality of power devices of the wafer.

Example 4 is The system of any one of Example 1-3, where the adapter circuit may include a first plurality of inputs and a first plurality of outputs, where the first plurality of inputs are coupled to a second plurality of outputs from the parametric system matrix and the first plurality of outputs are coupled to a second plurality of inputs for the probe circuit.

Example 5 is the system of any one of Example 1-4, where the one or more test and measurement instruments may include a pulse measure unit configured to generate pulses and to perform dynamic current and voltage measurements.

Example 6 is the system of any one of Example 1-5, where the adapter circuit is configured to determine a dynamic drain-source on-resistance for the power device.

Example 7 is the system of any one of Example 1-6, where the adapter circuit may include a voltage divider circuit, and one or more voltage protection circuits.

Example 8 is the system of any one of Example 1-7, where the probe circuit may include at least two low-current and low-voltage input pins.

Example 9 is the system of any one of Example 1-8, where the adapter circuit may include a block diode, a current limiter, a replaceable load circuit, a capacitor, and a sense resistor.

Example 10 is the system of any one of Example 1-9, where the replaceable load circuit is coupled to the power device through the probe circuit, and the replaceable load circuit is coupled in series to the current limiter and the block diode.

Example 11 is the system of any one of Example 1-10, where the capacitor and sense resistor is coupled in series to the power device through the probe circuit.

Example 12 is The system of any one of Example 1-11, where the voltage clamping circuit is coupled to the sense resistor, and the sense resistor is coupled to the power device through the probe circuit, where availability and functionality of the voltage clamping circuit enables accurate dynamic drain-source on-resistance (R_{DS}_{ₒₙ}) measurements.

Example 13 is the system of any one of Example 1-12, where the system is configured to run at least one test on the wafer, where the at least one test may include a dynamic drain-source on-resistance test, a double pulse test, a breakdown test, a leakage test, or a threshold voltage test.

Example 14 is The system of any one of Example 1-13, where the power device is a first power device, the parametric system matrix is coupled to a second power device of the wafer, and the system is configured to perform a first test on the first power device and a second test on the second power device simultaneously.

Example 15 is the system of any one of Example 1-14, where the power device is a transistor.

Example 16 is the system of any one of Example 1-15, where the adapter circuit is configured to perform a test on the power device using a Joint Electron Device Engineering Council (JEDEC) standard.

Example 17 is the system of any one of Example 1-16, further including a parametric system having the parametric system matrix.

Example 18 is the system of any one of Example 1-17, where the parametric system is configured to enable data analysis and parameter extraction using the adapter circuit and the probe circuit.

Example 19 is a method for testing a power device, including: coupling a probe circuit to a power device of a wafer, where the probe circuit is coupled to an adapter circuit, and the adapter circuit is coupled to a parametric system matrix; and performing a test on the power device by sending signals through the parametric system matrix and through the adapter circuit to the probe circuit.

Example 20 is the method of Example 19, where the test may include a dynamic drain-source on-resistance test, a double pulse test, a breakdown test, a leakage test, or a threshold voltage test.

The foregoing description has been set forth merely to illustrate example embodiments of present disclosure and is not intended to be limiting. Since modifications of the disclosed embodiments incorporating the substance of the invention may occur to person skilled in the art, the invention should be construed to include everything within the scope of the invention.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that all features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Also, when reference is made in this application to a method having two or more defined steps or operations, the defined steps or operations can be carried out in any order or simultaneously, unless the context excludes those possibilities.

Although specific examples of the disclosure have been illustrated and described for purposes of illustration, it will be understood that various modifications may be made without departing from the spirit and scope of the disclosure. Accordingly, the disclosure should not be limited except as by the appended claims.

What is claimed is:

1. A system for characterizing a power device, comprising:
a parametric system matrix coupled one or more test and measurement instruments;
an adapter circuit coupled to the parametric system matrix, the adapter circuit comprising a voltage clamping circuit coupled to the parametric system matrix; and
a probe circuit coupled to the adapter circuit and to the power device, wherein the power device is located on a wafer.

2. The system of claim 1, wherein the parametric system matrix is coupled to the probe circuit.

3. The system of claim 1, wherein the wafer comprises a plurality of power devices, and the power device is one of the plurality of power devices of the wafer.

4. The system of claim 1, wherein the adapter circuit comprises a first plurality of inputs and a first plurality of outputs, wherein the first plurality of inputs are coupled to a second plurality of outputs from the parametric system matrix and the first plurality of outputs are coupled to a second plurality of inputs for the probe circuit.

5. The system of claim 1, wherein the one or more test and measurement instruments comprises a pulse measure unit configured to generate pulses and to perform dynamic current and voltage measurements.

6. The system of claim 1, wherein the adapter circuit is configured to determine a dynamic drain-source on-resistance for the power device.

7. The system of claim 1, wherein the adapter circuit comprises a voltage divider circuit, and one or more voltage protection circuits.

8. The system of claim 1, wherein the probe circuit comprises at least two low-current and low-voltage input pins.

9. The system of claim 1, wherein the adapter circuit comprises a block diode, a current limiter, a replaceable load circuit, a capacitor, and a sense resistor.

10. The system of claim 9, wherein the replaceable load circuit is coupled to the power device through the probe circuit, and the replaceable load circuit is coupled in series to the current limiter and the block diode.

11. The system of claim 9, wherein the capacitor and sense resistor is coupled in series to the power device through the probe circuit.

12. The system of claim 9, wherein the voltage clamping circuit is coupled to the sense resistor, and the sense resistor is coupled to the power device through the probe circuit, wherein availability and functionality of the voltage clamping circuit enables accurate dynamic drain-source on-resistance (R_{DS}_{ₒₙ}) measurements.

13. The system of claim 1, wherein the system is configured to run at least one test on the wafer, wherein the at least one test comprises a dynamic drain-source on-resistance test, a double pulse test, a breakdown test, a leakage test, or a threshold voltage test.

14. The system of claim 1, wherein the power device is a first power device, the parametric system matrix is coupled to a second power device of the wafer, and the system is configured to perform a first test on the first power device and a second test on the second power device simultaneously.

15. The system of claim 1, wherein the power device is a transistor.

16. The system of claim 1, wherein the adapter circuit is configured to perform a test on the power device using a Joint Electron Device Engineering Council (JEDEC) standard.

17. The system of claim 1, further comprising a parametric system having the parametric system matrix.

18. The system of claim 17, wherein the parametric system is configured to enable data analysis and parameter extraction using the adapter circuit and the probe circuit.

19. A method for testing a power device, comprising:
coupling a probe circuit to a power device of a wafer, wherein the probe circuit is coupled to an adapter circuit, and the adapter circuit is coupled to a parametric system matrix; and
performing a test on the power device by sending signals through the parametric system matrix and through the adapter circuit to the probe circuit.

20. The method of claim 19, wherein the test comprises a dynamic drain-source on-resistance test, a double pulse test, a breakdown test, a leakage test, or a threshold voltage test.
